(19) United States
(12) Patent Application Publication
(10) Pub. No.: US 2009/0298222 A1
(43) Pub. Date: Dec. 3, 2009

(54) Method for manufacturing Chalcogenide devices

(75) Inventors: Tyler Lowrey, Rochester Hills, MI (US); Jeff Fournier, Livonia, MI (US); Robert Nuss, Westland, MI (US); Carl Schell, Waterford, MI (US); Guy Wicker, Southfield, MI (US); Jim Ricker, Woodhaven, MI (US); James Reed, Auburn Hills, MI (US); Ed Spall, Auburn Hills, MI (US); Sergey Kostylev, Bloomfield Hills, MI (US); Wolodymyr Czubatyj, Warren, MI (US); Regino Sandoval, Rochester Hills, MI (US)

Correspondence Address: Ovonyx, Inc, 2956 Waterview Drive, Rochester Hills, MI, 48309, US

(73) Assignee: Ovonyx, Inc.

(21) Appl. No.: 12/154,952

(22) Filed: May 28, 2008

(51) Int. Cl. H01L 45/00

(52) U.S. Cl. 438/102; 257/E45.002

(57) ABSTRACT

A method of chalcogenide device formation includes treatment of the surface upon which the chalcogenide material is deposited. The treatment reduces or eliminates native oxides and other contaminants from the surface, thereby increasing the adhesion of the chalcogenide layer to the treated surface, eliminating voids between the chalcogenide layer and deposition surface and reducing the degradation of chalcogenide material due to the migration of contaminants into the chalcogenide.

### CROSS-REFERENCE TO RELATED APPLICATIONS

### FIELD OF INVENTION

This invention pertains to phase change electronic devices, and, more particularly, to methods of producing phase change electronic devices that exhibit desirable resistance characteristics.

### BACKGROUND OF THE INVENTION

Phase-change electronic devices include memory devices, referred to herein as Ovonic Universal Memory (OUM), and switching devices, referred to herein as Ovonic Threshold Switches (OTS). OUM cells utilize a class of materials that are reversibly switchable from one material phase to another with measurable distinct electrical properties associated with each phase. For example, these materials may change between an amorphous disordered phase and a crystalline, or polycrystalline, ordered phase, with a significant corresponding change in the thermal and electrical conductivity of the material. Chalcogenide materials are typically employed as the phase change material used in both OUM and OTS cells. A wide range of chalcogenide compositions has been investigated in an effort to optimize the performance characteristics of chalcogenic devices. Chalcogenide materials generally include a chalcogen element and one or more chemical or structural modifying elements. The chalcogen element (e.g. Te, Se, S) is selected from column VI of the periodic table and the modifying elements may be selected, for example, from column III (e.g. Ga, Al, In), column IV (e.g. Si, Ge, Sn), or column V (e.g. P, As, Sb) of the periodic table. The role of modifying elements includes providing points of branching or cross-linking between chains comprising the chalcogen element. Column IV modifiers can function as tetracoordinate modifiers that include two coordinate positions within a chalcogenide chain and two coordinate positions that permit branching or crosslinking away from the chalcogenide chain. Column III and V modifiers can function as tricoordinate modifiers that include two coordinate positions within a chalcogenide chain and one coordinate position that permits branching or crosslinking away from the chalcogenide chain. Embodiments in accordance with the principles of the present invention may include binary, ternary, quaternary, and higher order chalcogenide alloys. Examples of chalcogenide materials are described in U.S. Pat. Nos. 5,166,758, 5,296,716, 5,414,271, 5,359,205, 5,341,328, 5,536,947, 5,534,712, 5,687,112, and 5,825,046 the disclosures of which are all incorporated by reference herein. Chalcogenide materials may also be the resultant of a reactive sputtering process: a chalcogenide nitride, or oxide, for example and chalcogenide may be modified by an ion implantation or other process.

Early work in chalcogenide devices demonstrated electrical switching behavior in which switching from a resistive state to a conductive state was induced upon application of a voltage at or above the threshold voltage of the active chalcogenide material. This effect is the basis of the Ovonic Threshold Switch (OTS) and remains an important practical feature of chalcogenide materials. The OTS provides highly reproducible switching at ultrafast switching speeds for over 10¹³ cycles. Basic principles and operational features of the OTS are presented, for example, in U.S. Pat. Nos. 3,271,591; 5,543,737; 5,694,146; and 5,757,446; the disclosures of which are hereby incorporated by reference, as well as in several journal articles including “Reversible Electrical Switching Phenomena in Disordered Structures,” Physical Review Letters, vol. 21, p. 1450-1453 (1969) by S. R. Ovshinsky; “Amorphous Semiconductors for Switching, Memory, and Imaging Applications,” IEEE Transactions on Electron Devices, vol. ED-20, p. 91-105 (1973) by S. R. Ovshinsky and H. Fritzsche; the disclosures of which are hereby incorporated by reference.

Another important application of chalcogenide materials is in electrical and optical memory devices. One type of chalcogenide memory device utilizes the wide range of resistance values available for the material as the basis of memory operation. Each resistance value corresponds to a distinct structural state of the chalcogenide material and one or more of the states can be selected and used to define operation memory states. Chalcogenide materials exhibit a crystalline state, or phase, as well as an amorphous state, or phase. Different structural states of a chalcogenide material differ with respect to the relative proportions of crystalline and amorphous phase in a given volume or region of chalcogenide material. The range of resistance values is generally bounded by a set state and a reset state of the chalcogenide material. By convention, the set state is a low resistance structural state whose electrical properties are primarily controlled by the crystalline portion of the chalcogenide material and the reset state is a high resistance structural state whose electrical properties are primarily controlled by the amorphous portion of the chalcogenide material.

Intermediate sub-states corresponding to various degrees of amorphization (or crystallization), with corresponding discernable differences in electrical properties such as resistivity, may be used to increase the information density of each OUM cell. Each memory state of a chalcogenide memory material corresponds to a distinct resistance value and each memory resistance value signifies unique informational content. Operationally, the chalcogenide material can be programmed into a particular memory state by providing an electric current pulse of an appropriate amplitude and duration to transform the chalcogenide material into the structural state having the desired resistance. By controlling the amount of energy provided to the chalcogenide material, it is possible to control the relative proportions of crystalline and amorphous phase regions within a volume of the material and to thereby control the structural (and corresponding memory) state of the chalcogenide material to store information.

Each memory state can be programmed by providing the current pulse characteristics of the state and each state can be identified, or “read”, in a non-destructive fashion by measuring the resistance. Programming among the different states is fully reversible and the memory devices can be written and read over a virtually unlimited number of cycles to provide robust and reliable operation. The variable resistance memory functionality of chalcogenide materials is currently being exploited in the OUM (Ovonic Universal (or Unified) Memory) devices that are beginning to appear on the market. Basic principles and operation of OUM type devices are presented, for example, in U.S. Pat. Nos. 6,859,390; 6,774,387; 6,687,153; and 6,314,014; the disclosures of which are incorporated by reference herein, as well as in several journal articles including, “Low Field Amorphous State Resistance and Threshold Voltage Drift in Chalcogenide Materials,” published in EE transactions on Electron Devices, vol. 51, p. 714-719 (2004) by Pirovana et al.; and “Morphing Memory,” published in IEEE Spectrum, vol. 167, p. 363-364 (2005) by Weiss.

The behavior (including switching, memory, and accumulation) and chemical compositions of chalcogenide materials have been described, for example, in the following U.S. Pat. Nos. 6,671,710; 6,714,954; 6,087,674; 5,166,758; 5,296,716; 5,536,947; 5,596,522; 5,825,046; 5,687,112; 5,912,839; and 3,530,441, the disclosures of which are hereby incorporated by reference. These references present proposed mechanisms that govern the behavior of chalcogenide materials. The references also describe the structural transformations from the crystalline state to the amorphous state (and vice versa) via a series of partially crystalline states in which the relative proportions of crystalline and amorphous regions vary during the operation of electrical and optical chalcogenide materials. The possibility of changing the phase of chalcogenic material from the amorphous to the crystalline state using electrical pulses is indeed not immediately apparent. In the amorphous state, the material resistivity is very high and the current flowing through the chalcogenic material would not allow a sufficient dissipation and thus a sufficiently high temperature. However, chalcogenic materials change their transport characteristics as a function of the applied electric field. Above a threshold voltage Vth, the structure begins to conduct, not because of a phase change, but because of a change in the electronic conduction mechanism. This behavior is called “electronic switching”; accordingly, biasing the chalcogenic structure to a voltage higher than the threshold voltage, it is possible to considerably increase the current flow. By directing this current through a suitable neighboring series resistor, which operates as a heater, it is thus possible to obtain, by Joule effect, a sufficient heating of the chalcogenic material for crystallization or amorphization.

There are a host of technical obstacles that, at least for the moment, prevent phase change memories from being the memory of choice for today's data storage applications. High “virgin resistance” (that is, the resistance exhibited by the chalcogenide as processed before any write operation), high set resistance, a limited number of read and write cycles, and inconsistencies, from cell to cell and from memory array to memory array, in all these characteristics placing obstacles for the widespread adoption of phase change memories.

A chalcogenide memory cell is operated by applying electrical pulses across a volume of chalcogenide material: a pulse having one profile “resets” the memory (by convention, places it in a higher-resistance, less-ordered state); a pulse of a different profile “sets” the memory (by convention, places it in a lower-resistance, more-ordered state; a pulse of yet a different profile, one of lesser magnitude than either the set or reset pulses, reads the state of the memory cell. The state of the memory cell corresponds to the resistance of the chalcogenide. Typically, the state (low resistance/high resistance, set/reset, 1/0), is read by applying a relatively low voltage across the chalcogenide and comparing the resultant current to a threshold current value. If the current is less than the threshold value, the cell is determined to be reset, if the current is greater than the threshold value, set. Alternatively, the state (low resistance/high resistance, set/reset, 1/0), can be read by passing a relatively low current through the chalcogenide and comparing the resultant voltage to a threshold value. If the voltage is greater than the threshold value, the cell is determined to be reset, if the voltage is less than the threshold value, set. Intermediate values may be correlated with intermediate states in multi-level logic schemes.

Ideally, the set and reset resistance values of a chalcogenide cell would be stable from its first programming operation to its last; a given programming current would always yield a given state-dependent (e.g. set or reset) resistance. However, when the initial resistance of a chalcogenide cell, R_{virgin}, is substantially higher than the programmed set resistance exhibited during subsequent operations, inconsistent programming of the set and reset resistances is often observed. To some extent, accommodation can be made for high initial resistance R_{virgin}. Although the mechanism is not completely understood, the chalcogenide may be conditioned by an initial cycling process that involves repeated setting and resetting of the chalcogenide. This conditioning reduces both the set and reset resistance of the chalcogenide to relatively stable, clearly defined levels.

However, in some cases, the R_{virgin} is prohibitively high and consistent set and reset resistances can't be achieved with a conditioning process. The cause(s) of such high R_{virgin} values can only be speculated upon, but their elimination is essential for the widespread introduction of chalcogenide devices into the marketplace. Similarly, the chalcogenide may exhibit a high set resistance Rₛₑₜ. Because the Rₛₑₜ resistance is typically the lowest resistance corresponding to a memory state, a high Rₛₑₜ tends to limit the number of resistive states that can readily be distinguished within the memory.

In addition, any or all of these conditions: high R_{virgin}, high Rₛₑₜ, or inconsistencies in R_{virgin}, Rₛₑₜ, or Rᵣₑₛₑₜ values could be predictive of the early failure (i.e. limited cycle life) of a chalcogenide memory. It should be noted that phase-change materials, their characteristics, and associated circuitry tend to be much more complex and less well understood than their conventional semiconductor counterparts. The interaction between phase-change materials, conductive electrodes, and semiconductors can affect composition, electrical, and thermal properties of the phase-change material in ways that are not, as yet, predictable. The composition of an electrode, for example, may affect the grain size of crystals formed within a region of phase change material that shares an interface with the electrode. Substances within an electrode or on the surface of an electrode or other surface could migrate into the phase change material or combine with the phase change material to form a film that interferes with the electrical and thermal paths employed by the phase change device. Other chalcogenide devices, such as ovonic threshold switches are also particularly susceptible to the deleterious effects of contaminants, which may create voids in the chalcogenide/deposition-surface interface, alter the composition of (and thereby degrade) the chalcogenide material, or reduce the adhesion between the chalcogenide and the deposition surface.

Native oxides and other contaminants may be formed on a deposition surface through a variety of processes. Native oxide typically forms as a result of exposing the exposed film layer/substrate to oxygen. Oxygen exposure may occur when moving substrates in air between processing chambers at atmospheric conditions, or when a small amount of oxygen remaining in a vacuum chamber contacts the wafer/film layer, or when a layer is exposed to foreign matter during etching. Other contaminants may be sputtered material from an oxide over-etch, residual photoresist or other materials from a stripping process, leftover hydrocarbon or fluorinated hydrocarbon polymers from a previous oxide etch step, or redeposited material from a sputter etch process. The native oxide and other contaminants create regions on the substrate which interfere with the electrical contact between the Chalcogenide film and the lower electrode, by creating regions where other materials are present. Outgassing of contaminants from the deposition surface or Chalcogenide film during deposition or subsequent heat steps can result in forming voids between the deposition surface and the chalcogenide. The presence of native oxides and other contaminants also can increase the lower electrode/chalcogenide contact resistance and can reduce the electromigration resistance of the chalcogenide. The contaminants can diffuse into the chalcogenide layer and alter the performance of chalcogenide-based devices.

A method that improves the adhesion between a deposition surface and deposited chalcogenide, that reduces or eliminates the occurrences of voids between a deposition surface and a chalcogenide layer, and that reduces or eliminates the presence of contaminants that could degrade the performance of a chalcogenide device would therefore be highly desirable.

### SUMMARY OF THE INVENTION

In a method in accordance with the principles of the present invention, a chalcogenide device is formed by depositing a thin film layer of chalcogenide material upon a treated surface (which may include an electrode), depositing a layer of electrode material on the chalcogenide layer, and patterning the chalcogenide/electrode stack to form an array of devices. The deposited chalcogenide material may be phase-change or threshold-switching material. The chalcogenide material may be deposited using any of a variety of methods, including, but not limited to: sputtering (physical vapor deposition (PVD)), chemical vapor deposition (CVD), metal organic chemical vapor deposition (MOCVD), or plasma enhanced chemical vapor deposition (PECVD), for example.

In accordance with the principles of the present invention, the surface upon which the chalcogenide material is deposited may be treated using any of a variety of processes, including dilute hydrogen fluoride bath, degassing, soft sputter etching, densification, and reactive plasma cleaning, or combinations thereof. Such pre-deposition treatment reduces or eliminates native oxides and other contaminants from the surface, thereby increasing the adhesion of the chalcogenide layer to the treated surface. Voids between the chalcogenide layer and deposition surface are substantially eliminated by eliminating the contaminants. Features within the deposition surface, such as pores, are more likely to be filled with chalcogenide material as a result of a surface treatment in accordance with the principles of the present invention. Contaminants that may otherwise migrate into the chalcogenide and degrade performance of the devices employing the chalcogenide are also eliminated. Because chalcogenide materials are susceptible to degradation by contaminants, the elimination of such contaminants is a critical benefit of a process in accordance with the principles of the present invention.

In an illustrative embodiment, a method of producing a circuit element (e.g. ovonic universal memory (OUM) or two- or three-terminal ovonic threshold switch (OTS) device) in accordance with the principles of the present invention includes the steps of forming an electrode on a substrate with insulator underneath and optionally on the sides of the electrode, optionally forming an insulator layer over the substrate and electrode and forming an opening in the insulator layer to provide electrical communication through the insulator layer to the electrode, performing a deposition preparation step, depositing chalcogenide material over the insulation layer(s) and electrode, depositing electrode material over the chalcogenide layer, patterning, and forming a plurality of devices.

In an illustrative embodiment, the deposition preparation step includes cleaning the deposition surface with a dilute hydrogen fluoride solution and then degassing the surface. In another illustrative embodiment, the deposition preparation step includes performing a soft sputter etch of the deposition surface. In another illustrative embodiment, the deposition preparation step includes performing a reactive plasma cleaning of the deposition surface. Because different types of chalcogenide material may be deposited upon different types of surface materials, using different features (e.g., a pore within the deposition surface) with various topologies, the optimum process or combination of processes for the manufacture of one type of chalcogenide device may not be the optimum process for the manufacture of another type of chalcogenide device. In accordance with the principles of the present invention, different surface preparation processes may be tested for use with a specific device type and the most effective of those processes used for production of that device type and similar device types. For example, for a given electrode material, insulator material, chalcogenide material, and device structure (e.g., planar or pore) various pre-deposition processes may be tested and one or more suitable processes selected from the group of processes for use in manufacture.

### BRIEF DESCRIPTION OF THE DRAWINGS

FIG. 1 is a flow chart depicting process flow for the manufacture of a chalcogenide device in accordance with the principles of the present invention; and

FIG. 2 is a more detailed flow chart depicting the process flow for manufacturing a chalcogenide device in accordance with the principles of the present invention.

### DETAILED DESCRIPTION

Although this invention will be described in terms of certain preferred embodiments, other embodiments that are apparent to those of ordinary skill in the art, including embodiments that do not provide all of the benefits and features set forth herein, are also within the scope of this invention. Various structural, logical, process step, and electrical changes may be made without departing from the spirit or scope of the invention.

The term “substrate” used in the following description may include any supporting structure including, but not limited to, a semiconductor substrate that has an exposed electrically conducting surface. The term semiconductor substrate may include, for example, silicon on insulator (SOI), silicon on sapphire (SOS), doped and undoped semiconductors, epitaxial layers of silicon supported by a base semiconductor foundation, and other semiconductor structures. When reference is made to substrate, semiconductor substrate, or wafer in the following description, previous process steps may have been used to form regions, junctions, and complex structures, including but not limited to a microprocessor or microcontroller, for example, in or over the base semiconductor or foundation.

The term “chalcogenide glass,” or simply chalcogenide, is intended to include substances that comprise at least one device from group VIA (or group 16) of the periodic table. Group VIA elements (e.g., O, S, Se, Te, and Po) are also referred to as chalcogens. Both memory (OUM) and switching (OTS) devices may benefit from the methods and apparatuses described herein. For the sake of brevity and clarity of description, reference will be made primarily to OUM devices in the following discussion. Accordingly, the scope of the invention is defined only by reference to the appended claims.

In a method in accordance with the principles of the present invention, a chalcogenide device is formed by depositing a thin film layer of chalcogenide material upon a treated surface (which may include an electrode), depositing a layer of electrode material on the chalcogenide layer, and patterning the chalcogenide/electrode stack to form an array of devices. The deposited chalcogenide material may be phase-change or threshold-switching material. The chalcogenide material may be deposited using any of a variety of methods, including, but not limited to: sputtering (physical vapor deposition (PVD)), chemical vapor deposition (CVD), metal organic chemical vapor deposition (MOCVD), or plasma enhanced chemical vapor deposition (PECVD), for example.

In accordance with the principles of the present invention, the surface upon which the chalcogenide material is deposited may be treated using any of a variety of processes, including dilute hydrogen fluoride bath, degassing, soft sputter etching, densification, and reactive plasma cleaning, or combinations thereof. Such pre-deposition treatment reduces or eliminates native oxides and other contaminants from the surface, thereby increasing the adhesion of the chalcogenide layer to the treated surface. A more consistent and reliable electrical contact is made between the chalcogenide layer and bottom electrode as a result of the pre-deposition treatment. Voids between the chalcogenide layer and deposition surface are substantially eliminated by eliminating the contaminants. Features within the deposition surface, such as pores, are more likely to be filled with chalcogenide material as a result of a surface treatment in accordance with the principles of the present invention. Contaminants that may otherwise migrate into the chalcogenide and degrade performance of the devices employing the chalcogenide are also eliminated. Because chalcogenide materials are susceptible to degradation by contaminants, the elimination of such contaminants is a critical benefit of a process in accordance with the principles of the present invention. Example chalcogenide materials include: GeSbTe 225 (OUM material) and AsGeInSiTe 35/7/0.25/18/40 (OTS material). Example electrode materials include: TiAlN, TiSiN, TiN. Example insulator materials include: SiO2, SiNx, and Al2O3. As is known in the art, additional layers, (beyond the basic layers of electrode, chalcogenide, and electrode) may be included in the structure of a device in accordance with the principles of the present invention. Such layers may include thermal oxide layers and multi-layer electrodes that include a conductive layer formed from TiW or a combination of Ti and TiN and a carbon barrier layer, for example.

Native oxides and other contaminants may be present on a pre-deposition surface in a number of ways. Native oxide typically forms as a result of exposing the surface to oxygen. Oxygen exposure occurs when moving substrates in air between processing chambers at atmospheric conditions, or when a small amount of oxygen remaining in a vacuum chamber contacts the surface, or when a surface is exposed to foreign matter during etching. Other contaminants may include sputtered material from an oxide over-etch, residual photoresist or other materials from a stripping process, leftover hydrocarbon or fluorinated hydrocarbon polymers from a previous oxide etch step, or redeposited material from a sputter etch process, for example. The native oxide and other contaminants may create regions on the pre-deposition surface which interfere with the electrical contact between the Chalcogenide film and the lower electrode by creating regions where other materials are present. Outgassing of contaminants from the deposition surface or Chalcogenide film during deposition or subsequent heat steps can result in forming voids between the deposition surface and the chalcogenide.

Chalcogenide devices sometimes employ pores that operate to enclose chalcogenide material in thermally insulative material. For a variety of reasons, it may be desirable to employ high aspect ratio pores with such devices (that is, pores with the ratio of the height of the pore to the width of the pore being greater than 1). The presence of other contaminants within a narrow feature such as a high aspect ratio pore may aggravate the aforementioned deleterious effects because contaminants can be trapped in the partially enclosed structure.

The presence of native oxides and other contaminants also can increase the contact resistance of a chalcogenide device in an uncontrolled manner. That is, the contact resistance of neighboring devices may vary widely, depending upon the presence or absence of native oxides or other contaminants on the deposition surface at the time chalcogenide is deposited. Contaminants can diffuse into the dielectric layer, bottom electrode, and/or the deposited chalcogenide and alter the performance of devices, particularly those that include the small features, such as high aspect ratio pores.

In an illustrative embodiment, a method of producing a circuit element (e.g. ovonic universal memory (OUM) or two- or three-terminal ovonic threshold switch (OTS) device) in accordance with the principles of the present invention includes the steps of forming an electrode on a substrate with insulator underneath and optionally on the sides of the electrode, optionally forming an insulator layer over the substrate and electrode and forming an opening in the insulator layer to provide electrical communication through the insulator layer to the electrode, performing a deposition preparation step, depositing chalcogenide material over the insulation layer and electrode, depositing electrode material over the chalcogenide layer, patterning, and forming a plurality of devices.

In an illustrative embodiment, the deposition preparation step includes cleaning the deposition surface with a dilute hydrogen fluoride solution and then degassing the surface. The degassing process may be performed by placing a partially completed wafer (i.e. a wafer that includes a substrate, bottom electrodes, an insulator layer, and openings within the insulator layer to the bottom electrodes) in a chamber within a deposition tool, the chamber pumped to a target vacuum level and held at that vacuum level for a prescribed period of time. Additionally, the wafer may be exposed to elevated temperatures for a prescribed period of time to accelerate the de-gassing process. In another illustrative embodiment, the deposition preparation step includes performing a soft sputter etch of the deposition surface. In another illustrative embodiment, the deposition preparation step includes performing a reactive plasma cleaning of the deposition surface. The deposition preparation step may also include a densification step performed upon the insulator layer before a chalcogenide layer is deposited. Such a densification step may be carried out using any of a variety of mechanisms or techniques, such as a rapid thermal processing (RTP), baking in a furnace, exposing the insulator to a plasma, or other means.

Because different types of chalcogenide material may be deposited upon different types of surface materials, using different features (e.g., a pore within the deposition surface) the optimum process or combination of processes for the manufacture of one type of chalcogenide device may not be the optimum process for the manufacture of another type of chalcogenide device. In accordance with the principles of the present invention, different surface preparation processes may be tested for use with a specific device type and the most effective of those processes used for production of that device type and similar device types. For example, for a given electrode material, insulator material, chalcogenide material, and device structure (e.g., planar or pore) various pre-deposition processes may be tested and one or more suitable processes selected from the group of processes for use in manufacture. Process steps that take place after the electrode and insulator layers are formed on a substrate but before the phase change material is deposited, including; insulator densification, dilute hydrogen fluoride immersion, degassing, reactive plasma cleaning, and soft sputter etching, are contemplated within the scope of a process for producing a phase change or threshold-switching circuit element in accordance with the principles of the present invention.

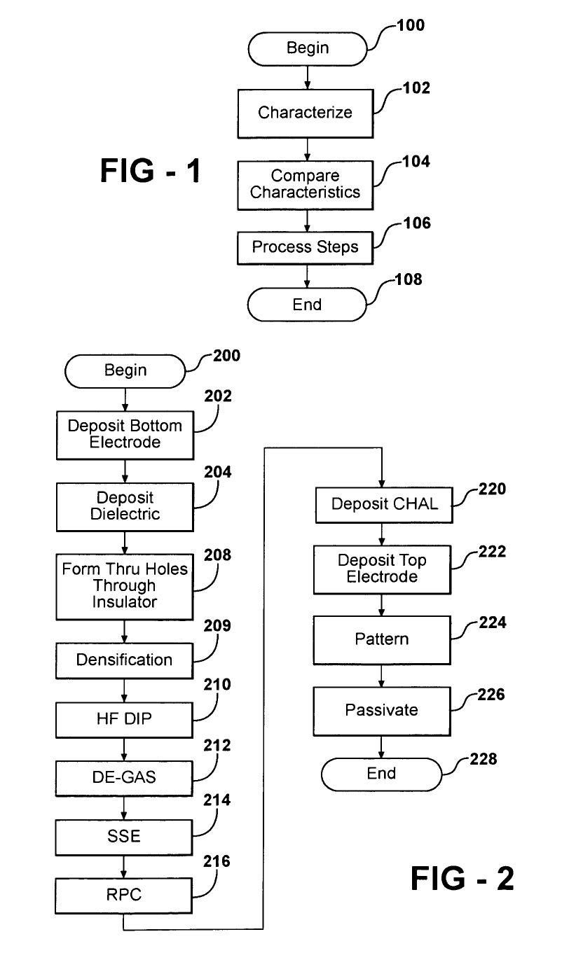

The flow chart of FIG. 1 depicts the steps involved in the formation of a chalcogenide electronic device in accordance with the principles of the present invention. The process begins in step 100 and proceeds from there to step 102. In step 102 one or more partially completed wafers are characterized. The wafers include a substrate that may include complex integrated circuit structures, such as microprocessor cores, for example, and may be referred to as wafers or, simply, as substrates herein. At this stage, in addition to circuitry formed within the substrate, the wafers may include a layer of electrode material that will be used to form the bottom electrodes of chalcogenide devices and a layer of dielectric material. The layer of dielectric material may have features, such as pores, that provide access to the electrode layer below, for example. This characterization step may be something as simple as noting the nominal composition of the electrode and insulator layers, for example, and correlating those nominal values to characteristics of previously manufactured wafers. Alternatively, the surface structure of both the electrode and insulator layers may be examined using analytical tools such as a scanning electron microscope and the composition of the electrode and insulator may be analyzed by X-ray Fluorescence (XRF) or Auger Electron Spectroscopy (AES), for example. Electrical characteristics of the electrodes and insulator layer may also be employed to characterize a set of wafers scheduled for manufacture. The phase change material to be deposited may be similarly characterized in this step. Such characterization may simply involve taking note of the type of sputtering target or MOCVD precursors, for example.

From step 102 the process proceeds to step 104 where a comparison is made between the characteristics measured in step 102 and characteristics of previously characterized wafers (e.g., electrode material and thickness, insulator material and thickness, etc.,) and chalcogenide materials (type and thickness of chalcogenide to be deposited, etc.). For wafers and chalcogenide materials having exactly-matching or similar characteristics, the same deposition procedures may be employed as have been successfully employed in the past (including parameters such as duration, temperature, and pressure, for example). If no data is available, a projection may be made as to whether existing techniques may be successfully employed with the new materials. If the materials and processes are too dissimilar, a test run may be performed on one or more samples of the new wafer/chalcogenide material combination and one or more steps in accordance with the principles of the present invention, as described in greater detail below, may be employed to prepare a wafer or set of wafers for deposition in accordance with the principles of the present invention.

After characterizing the wafer in step 102 and comparing those characteristics to previously characterized wafers and chalcogenide materials and, in step 104, determining which processes in accordance with the principles of the present invention should be employed in preparation of the current wafer, the process proceeds to step 106 where one or more steps in accordance with the principles of the present invention are employed to prepare a wafer for deposition of chalcogenide material. Characteristics of wafers, chalcogenide materials, and effective preparation treatments may be stored and compared and projections of suitability may be made electronically to determine the most suitable set of steps to employ in preparing a current wafer of interest for deposition.

In step 106 one or more of the processing steps described in greater detail in the discussion related to FIG. 2 are performed prior to depositing chalcogenide material over the electrodes and insulator. In accordance with the principles of the present invention, any of the following process steps that are employed in preparation for chalcogenide material deposition is preferably performed no more than a given Q time or staging time between surface prep and the chalcogenide material deposition over the electrode and insulator layers. The maximum staging or Q time can vary depending on the pre-treatment used, the electrode and insulator materials, the Chalcogenide material, and method for deposition. Q times can vary from <1 hour to <4 hours to <1 day to <1 week. Whenever practicable, wafers treated with one or more of the surface preparation treatments prior to chalcogenide deposition processes are maintained (staged) in an inert, dry, room-temperature environment if not immediately introduced to the chalcogenide deposition step. Additionally, in accordance with the principles of the present invention, the deposition step may be optimized by tailoring it to a particular run or type of wafers, as described in greater detail below.

Generally, if during an initial characterization such as takes place in step 102, one of the procedures or a combination of the procedures described below has proven effective at creating chalcogenide devices (as indicated by, for example, Rvirg or Rset values) using a similar wafer type and chalcogenide material type as are going to be deposited, the procedure or combination thereof, is employed again. Typically, a minimal set of procedures is employed to achieve the desired Rvirgin, Rset or other electrical parametric values. That is, rather than incurring the expense associated with using all the processes discussed below, a procedure may be developed that allows one to employ only a subset of the processes, thereby realizing acceptable performance at a reasonable cost. From step 106 the process proceeds to end in step 108.

The flow chart of FIG. 2 depicts an illustrative process flow for chalcogenide device formation in accordance with the principles of the present invention. The depicted process flow is meant for illustrative purposes only. Steps in the flow may be substituted, rearranged, or deleted, depending upon electrode, dielectric, and chalcogenide characteristics, for example.

In this illustrative embodiment the process begins in step 200 and proceeds to step 202, where a layer of bottom electrode material is deposited over a substrate. As previously noted, the substrate may include previously formed electronic devices and circuits. The bottom electrode material may be deposited using any of a variety of thin film deposition methods, including sputtering (physical vapor deposition (PVD)), or MOCVD, for example. From step 202, the process proceeds to step 204 where a layer of dielectric material, such as SiO₂ is deposited over the layer of electrode material. The dielectric layer may also be deposited using any of a variety of known deposition techniques.

In step 208 openings, such as pores may be formed in the dielectric layer using a process, such as a conventional photo-etching process that includes masking, developing, and etching steps, such as are known in the art. Typically, the dielectric layer is between about 100 Å and about 3000 Å thick. Preferably, the dielectric layer is between about 200 Å and about 2000 Å thick. More preferably, the dielectric layer is between about 300 Å and about 1500 Å thick. The apertures formed in the dielectric layer may be circular pores having a diameter of between about 1 nm and about 200 nm. Preferably, the pores will have a diameter of between about 5 nm and about 150 nm. More preferably, the pores will have a diameter of between about 10 nm and about 100 nm. In accordance with the principles of the present invention the apertures may be more complex structures that include, for example, sloped sidewalls. After the dielectric layer is etched, the features (e.g., pores) may include resist or electrode residues from over-etching of the dielectric layer, for example. Residual photoresist, from the photoresist stripping and/or ashing process or residual hydrocarbon or fluorinated hydrocarbon polymers from the dielectric etch step, may also be located within the pore and/or on the surface of the dielectric layer.

From step 208 the process proceeds to step 209 where an optional densification process may be carried out. In such a process, a wafer is subjected to an insulator densification step before chalcogenide material is deposited atop the insulator and electrode surfaces. In an illustrative embodiment, insulator densification is carried out at a relatively high temperature in a relatively inert environment. To that end, a wafer, or batch of wafers, may be processed in an inert environment inside a furnace, a rapid thermal processing chamber, or a plasma chamber, for example. A pure argon or N2 atmosphere within the chamber would provide a suitably inert environment, but other inert environments are contemplated within the scope of a process in accordance with the principles of the present invention. Once a wafer is placed in the chamber, the temperature is raised to a “bake” temperature and maintained at that temperature for a prescribed period of time. In an illustrative embodiment, 450 C to 750 C is a preferred range for the bake temperature and 10-300 minutes is a preferred range of time for the bake. Generally, a shorter bake period requires a higher temperature so that, for example, a 450 C bake may require 200 minutes, while a 750 C bake may require only 20 minutes. Not wishing to be bound by theory, it is believed that the desorbtion or vaporization of impurities such as water or H from insulator or bottom electrode surfaces that often accompanies insulator densification may improve adhesion between the insulator and deposited chalcogenide, thereby improving the interface.]

From step 209 the process proceeds to step 210 where the deposition surface is cleaned with a dilute hydrogen fluoride solution. In an illustrative embodiment, a mixture of deionized water for dilution of hydrogen fluoride is employed to prepare the electrode and insulator surfaces. The ratio of deionized water to hydrogen fluoride may be from approximately 50:1 to 500:1 and the duration of the treatment may range from five seconds to five minutes. Preferably, the ratio of deionized water to hydrogen fluoride may be between about 50:1 to about 100:1 and the duration of the treatment, from fifteen seconds to 2 minutes. In accordance with the principles of the present invention, the deionized water/hydrogen fluoride mixture is allowed to flow across the surfaces of the electrodes and insulator or, the entire wafer is immersed in the dilute hydrogen fluoride solution. The duration of the treatment depends upon the ratio of deionized water to hydrogen fluoride. In particular, because hydrogen fluoride is highly reactive, a solution containing a high concentration of hydrogen fluoride may quickly etch the insulator and electrode surfaces. Although the process may be tailored to individual electrode and insulator materials, generally, in accordance with the principles of the present invention, a tradeoff is made between the extent of the pre-treatment and the amount of removal of the surface materials. For example, in an illustrative embodiment, a wafer is immersed in a dilute, 500 to 1, deionized water to hydrogen fluoride solution for up to five minutes. Generally, the duration of the treatment may range from five seconds to five minutes, but subranges (e.g. fifteen seconds to thirty seconds) may be advantageously employed for particular insulator/electrode/chalcogenide material pairings.

From step 210 the process proceeds to step 212 where the deposition surface is de-gassed. The degas step is advantageous in promoting desorbtion of gasses or other foreign compounds that have been absorbed into the insulator or bottom electrode from prior processing steps. Because a dilute hydrogen fluoride cleaning step, such as may take place in step 208, may introduce water or hydrogen into the insulator material, a degas step is of particular utility in the case where a dilute hydrogen fluoride bath is employed in a chalcogenide device formation process in accordance with the principles of the present invention. In an illustrative embodiment, this process may be carried out in-situ (i.e. in the deposition chamber), prior to the deposition of chalcogenide material. In such an embodiment a wafer is placed in a deposition chamber, the chamber is pumped to the level of vacuum that is employed during the deposition process, the temperature is elevated, and the wafer is left to “bake” in vacuum for an extended period of time. The period of time, temperature, and level of vacuum may differ, for example, according to which of the other processes in accordance with the principles of the present invention have been employed, according to the composition of the electrode and insulator, and according to the composition of the chalcogenide material that is to be deposited. In an illustrative embodiment, the de-gasification is carried out for a period of from fifteen seconds to thirty minutes. In a preferred embodiment, the degasification is carried out for a period between thirty seconds and ten minutes. In a still more preferred embodiment, the degasification is carried out for a period between one and five minutes. This duration is measured from the time the chamber reaches a target temperature (between 100° C. and 500° C., but preferably between 150° C. and 400° C., and more preferably between 200° C. and 350° C. and target vacuum level (between 0.1 mtorr and 1000 mtorr, preferably between 0.5 mtorr and 100 mtorr, more preferably between 3 mtorr and 20 mtorr). In accordance with the principles of the present invention, after the de-gasification process is carried out, the chamber may be brought back to a temperature suitable for deposition and the deposition performed while the wafer remains in the chamber under vacuum.

From step 212 the process proceeds to step 214 where, in accordance with the principles of the present invention, a wafer may be subjected to an in-situ soft sputter etch before chalcogenide material is deposited over the electrode and insulator surfaces. This process may be carried out immediately prior to the deposition of chalcogenide material (e.g. immediately after a de-gasification step such as just described) In such an embodiment a wafer is placed in a deposition chamber and the chamber is pumped to the level of vacuum that is employed during the deposition process. Rather than employing a deposition target, however, the wafer itself acts as the target of a plasma's positive ions. The ions strip away a portion of the electrode and insulator surfaces. Because the plasma power applied to the wafer is generally considerably less than typically employed in a sputtering process, the etching process is referred to as a “soft” etch. In an illustrative embodiment, the etch may be performed for a period of from thirty seconds to one minute and may etch from ten to two hundred angstroms equivalent oxide removal.

While not wishing to be bound by theory, it is believed that a soft sputter etch removes contaminants from the electrode's surfaces that would, should they remain, disrupt the interface between the chalcogenide material and the electrode. It is believed that contaminants may pose an undesirable high impedance barrier between chalcogenide material and the electrodes upon which the material is deposited. Additionally, as mentioned earlier, various sorts of contaminants may lead to the separation of chalcogenide material from the electrode (voiding). And it is possible that contaminants may be absorbed by and become a part of chalcogenide material deposited over contaminants. This sort of incorporation of contaminants into the chalcogenide material could undesirably alter the material's electrical and thermal properties. The mechanism for such interference may vary according to the materials, but removing the contaminants denies them the opportunity to disrupt the interface, regardless of the mechanism. It is believed that the elimination of these materials allow the chalcogenide and electrode materials to bond in a manner that provides good thermal and electrical contact between the two. Such bonding may include the migration of materials between the chalcogenide and electrode regions and may alter the stoichiometric, chemical, and structural makeup of both regions locally. Such transformations may allow for improved short term performance as well as longer cycle life. Improved adherence to the insulator may also improve the overall mechanical properties of the device. A judicious application of a soft sputter etch may prove effective at improving the interfaces between electrodes, insulator, and deposited chalcogenide material. It should be noted that a sputter etch can physically damage layers by physical bombardment, sputter re-deposition of Si/SiO₂ onto sidewalls of the features, and sputter re-deposition of electrode material onto sidewalls of the features. Redeposited material generated by a sputter etch process may foul the deposition surfaces, particularly in high aspect ratio features, such as pores. These re-deposited materials can migrate into the dielectric layer or bottom electrodes. The presence of the re-deposited materials also can affect the resistance of the deposited chalcogenide by substantially narrowing the width of a feature, such as a pore. For these reasons, a soft sputter etch process must be optimized and tightly controlled in order to be effective.

From step 214 the process proceeds to step 216 where a reactive plasma cleaning process may be carried out in accordance with the principles of the present invention. The reactive plasma cleaning process may employ hydrogen or nitrogen as the reactive cleaning agent, for example. Preferably, the substrate is transferred into a cleaning chamber after the dielectric layer and bottom electrode has been formed and features, such as pores, have been formed in the dielectric layer. Once the substrate is positioned for processing in the cleaning chamber, the chamber pressure is reduced to a value in the range of about 10 to 1000 mtorr. More preferably the chamber pressure is reduced to a value in the range of about 20 to 500 mtorr. Even more preferably, the chamber pressure is reduced to a value in the range between 30 and 300 mtorr. Next, a processing gas consisting essentially of hydrogen (or nitrogen) and helium, comprising between about 5% and about 100% hydrogen (nitrogen) by number of atoms, is introduced into the processing region. Preferably, the processing gas comprises about 2%-20% hydrogen and the remainder helium. More preferably, the processing gas comprises about 5% hydrogen and 95% Helium. A plasma of the hydrogen/helium gas is struck in the processing region to subject the substrate to a reactive hydrogen (nitrogen) plasma environment. The hydrogen (or nitrogen) plasma is generated by applying between about 25 W and 750 W, (preferably between 50 W and 500 W, more preferably between 100 W and 400 W) from an RF power source to an RF electrode. The hydrogen plasma is maintained for between about 5 seconds and 1000 seconds (preferably between 10 seconds and 500 seconds, more preferably between about 20 seconds and 300 seconds) to clean the substrate.

Once the reactive plasma cleaning process is completed, the pre-clean chamber is evacuated to exhaust the processing gas and the reacted byproducts generated by the cleaning process.

From step 216 the process proceeds to step 220 where chalcogenide material is deposited. In accordance with the principles of the present invention, the deposition process itself may be carried out in a manner that likely will improve the interface between electrodes and chalcogenide material. This novel deposition process may be performed at a chamber temperature within the range of approximately 20° C. to 300° C., with temperatures within the range of 100° C. to 250° C. preferred.

After deposition of the chalcogenide material, the process proceeds to step 222 where top electrode material is deposited on the chalcogenide layer. From there, devices may be patterned using known photolithographic techniques in step 224, passivated in step 226, and on to end in step 228.

1. A method, including the steps of:
forming a surface upon a substrate;
preparing the surface for deposition; and
depositing a thin film of chalcogenide material upon the surface, wherein the step of preparing the surface for deposition includes at least one member of the following group of surface preparation methods: dilute hydrogen fluoride cleaning, soft sputter etching, degassing, surface densification, and reactive plasma cleaning.

2. The method of claim 1 wherein the step of forming a surface upon a substrate includes the step of forming a surface upon a single-crystalline substrate.

3. The method of claim 1 wherein the step of forming a surface upon a substrate includes the step of forming a surface upon a non-single-crystalline substrate.

4. The method of claim 1 wherein the step of depositing a thin film of chalcogenide material includes the step of depositing a thin film of phase change material.

5. The method of claim 1 wherein the step of depositing a thin film of chalcogenide material includes the step of depositing a thin film of threshold-switching material.

6. The method of claim 1 wherein the step of forming a surface upon a substrate includes the steps of forming an electrode on a substrate;
forming an insulator layer over the substrate; and
forming an opening in the insulator layer to provide electrical communication through the insulator layer to the electrode.

7. A method, comprising the steps of:
forming a surface for deposition;
performing dilute a hydrogen fluoride cleaning of the surface;
degassing the surface; and
depositing a layer of chalcogenide material on the surface.

8. The method of claim 7 wherein the step of forming a surface includes the steps of:
forming an electrode on a substrate;
forming an insulator layer over the substrate; and
forming an opening in the insulator layer to provide electrical communication through the insulator layer to the electrode.

9. The method of claim 7 further comprising the step of reactively plasma cleaning the surface.

10. The method of claim 9 further comprising the step of performing a densification of the insulator layer.

11. The method of claim 10 wherein the step of depositing a layer of chalcogenide material on the surface includes the step of depositing the chalcogenide at a temperature between 100C and 250C.

12. A method, comprising the steps of:
forming a surface for deposition;
performing soft sputter etch upon the surface; and
depositing a layer of chalcogenide material on the surface.

13. The method of claim 12 wherein the step of forming a surface includes the steps of:
forming an electrode on a substrate;
forming an insulator layer over the substrate; and
forming an opening in the insulator layer to provide electrical communication through the insulator layer to the electrode.

14. The method of claim 12 further comprising the step of performing an RPC step on the surface.

15. The method of claim 14 further comprising the step of performing a densification of the insulator layer.

16. The method of claim 15 wherein the step of depositing a layer of chalcogenide material on the surface includes the step of depositing the chalcogenide at a temperature between 100C and 250C.

17. A method, comprising the steps of:
forming a surface for deposition;
performing reactive plasma clean upon the surface; and
depositing a layer of chalcogenide material on the surface.

18. The method of claim 17 wherein the step of forming a surface includes the steps of:
forming an electrode on a substrate;
forming an insulator layer over the substrate; and
forming an opening in the insulator layer to provide electrical communication through the insulator layer to the electrode.

19. The method of claim 17 further comprising the step of performing a densification step on the surface.

20. The method of claim 19 further comprising the step of performing a densification of the insulator layer.

21. The method of claim 20 wherein the step of depositing a layer of chalcogenide material on the surface includes the step of depositing the chalcogenide at a temperature between 100C and 250C.
